(19) United States
(12) Patent Application Publication
(10) Pub. No.: US 2025/0321139 A1
(43) Pub. Date: Oct. 16, 2025

(54) Optical Sensor

(71) Applicant: Leuze electronic GmbH + Co. KG, Owen/Teck (DE)

(72) Inventors: Jörg Droemer, Bad Urach-Wittlingen (DE); Reza Kharrazian, Reutlingen (DE); Thomas Dümmel, Hülben (DE)

(21) Appl. No.: 19/173,912

(22) Filed: Apr. 9, 2025

(30) Foreign Application Priority Data
Apr. 10, 2024 (DE) 202024101732.3

(51) Int. Cl. G01J 1/02; G01J 1/04; G01J 1/44; G06K 7/10

(52) U.S. Cl. CPC G01J 1/0252; G01J 1/0271; G01J 1/0411; G01J 1/44; G06K 7/10831

(57) ABSTRACT

An optical sensor (1) with a housing (2) wherein at least one sensor component designed for object detection as well as electronic components are arranged. At least one of the electronic components generates an output signal in dependence upon sensor signals of the sensor components. The sections of the housing (2) consisting of heat-conductive material are connected to an electronic component and/or the sensor component via thermal conduction layers (15) such that heat generated therein is dissipated to the exterior via the housing (2).

### CROSS REFERENCE TO RELATED APPLICATIONS

This application claims the priority of DE 202024101732.3 filed on 2024 Apr. 10; this application is incorporated by reference herein in its entirety.

### BACKGROUND

The invention relates to an optical sensor.

Such optical sensors are generally used for detecting objects. For this purpose, the optical sensor has sensor components and electronic components integrated in a housing.

As sensor components, the optical sensor typically has a light beam-emitting transmitter unit and a receiver unit which receives light beams reflected back by an object.

At least one of the electronic components forms an evaluation unit in which an output signal is generated in dependence upon sensor signals of the sensor component.

The optical sensor can be used for detecting objects within a monitoring area. In this case, as the output signal, the optical sensor generates an object detection signal that signals whether an object is present in the monitoring area, or not.

The optical sensor can be used to detect codes, in particular, such as e.g. barcodes or 2D codes, i.e. the optical sensor forms a code reader. In this case, the code information contained in the sensor signals of the receiver unit is decoded in the evaluation unit, such that the detected code can be output as the output signal.

With an embodiment in the form of a code reader, in particular, the receiver unit is designed in the form of an image sensor, i.e. an imager. Advantageously, a transmitter unit in the form of an illumination unit having, for example, a multiple arrangement of light-emitting diodes, is assigned to the image sensor.

Advantageously, the image sensor is connected to a computer unit forming the evaluation unit by MIPI lines. MIPI lines are serial interface lines standardized by the MIPI consortium with high and rapid data transmission rates.

One problem in this regard is that such MIPI lines are highly susceptible to disturbances at longer lengths.

Another general problem with optical sensors is that their interior is heated by the heating power of the electronic components and sensor components, which can result in functional impairments or even in failures of the optical sensor.

The problem which the present invention seeks to solve is to design an optical sensor of the type mentioned at the beginning such that it has a low susceptibility to disturbances.

The features of claim 1 are provided to solve this problem. Advantageous embodiments of the invention and appropriate further developments are described in the dependent claims.

### SUMMARY

The invention relates to an optical sensor (1) with a housing (2) wherein at least one sensor component designed for object detection as well as electronic components are arranged. At least one of the electronic components generates an output signal in dependence upon sensor signals of the sensor components. The sections of the housing (2) consisting of heat-conductive material are connected to an electronic component and/or the sensor component via thermal conduction layers (15) such that heat generated therein is dissipated to the exterior via the housing (2).

### DETAILED DESCRIPTION

The invention relates to an optical sensor with a housing in which are arranged at least one sensor component designed for object detection as well as electronic components. At least one of the electronic components generates an output signal in dependence upon sensor signals of the sensor component. Sections of the housing consisting of heat-conductive material are connected to an electronic component and/or the sensor component via thermal conduction layers such that heat generated therein is dissipated to the exterior via the housing.

An essential advantage of the invention is that heat arising in the interior due to the heating power of the sensor components and electronic components can be efficiently conducted to the exterior, i.e. to the surroundings of the optical sensor. Thereby overheating of the electronic components and sensor components, and malfunctions or even failures of the optical sensor caused thereby, can be prevented. This effect can be augmented yet further when the outside of the housing is painted with heat dissipation paint.

An essential aspect of the invention is that the housing consists entirely or at least by sections of a heat-conductive material, i.e. a material with high heat conductivity. Thereby heat can be dissipated to the exterior by the housing of the optical sensor via heat conduction.

A further essential aspect of the invention is that the housing structure of the housing of the optical sensor is designed such that housing segments directly touch electronic components and/or sensor components and are connected thereto via thin heat conduction layers. Thus direct heat transfer from the electronic component, or respectively sensor component, via the thermal conduction layer to the housing segment, and thus the entire housing is achieved, which ensures direct dissipation of heat arising in the region of the electronic component or of the sensor component.

The housing segment or housing segments can protrude from insides of housing walls of the housing and from there be guided directly to the electronic components or sensor components.

Especially advantageously, the housing consists of a heat-conductive metallic material.

Metallic materials have very high heat conductivity values and are therefore especially suitable for dissipating heat from the interior of the housing.

According to an advantageous embodiment, the metallic material is a zinc or aluminum die-cast.

Housings made of zinc or aluminum die-cast parts can be produced efficiently. Moreover, it is advantageous that they can be used to realize even complex housing geometries.

The heat conduction layers generally have low layer thicknesses, which advantageously lie in the μm range. This ensures good heat transfer to the housing structures.

Advantageously a thermal conduction pad or thermal paste is provided as the heat conduction layer.

Since it is a large planar part, the printed circuit board generates considerable heat during operation of the optical sensor, as do, in particular, further electronic components present on the printed circuit board.

The direct coupling of the printed circuit board to the housing cover or a housing wall, which are respectively heat conductive, via the heat conduction layers allows for efficient dissipation of heat arising in the region of the printed circuit board from the interior of the housing.

In general, the surface of the printed circuit board itself or the surface of a further electronic component placed on the printed circuit board can be directly connected to the heat conductive layer.

According to a further advantageous embodiment, a cooling body opens out on the insides of housing wall segments consisting of heat-conductive material, the cooling body consisting of heat conductive material and being a constituent of the housing, i.e. the cooling body is designed monolithically with the housing body of the housing, which forms an enclosure for sensor and electronic components. Alternatively, the cooling body can be heat-conductively connected to the housing body, for example by a screw connection. The cooling body is in contact with at least one electronic component via at least one thermal conduction layer.

In particular, the cooling body is in contact with the top of the printed circuit board via at least one thermal conduction layer.

As a constituent of the housing, the geometry of the cooling body is optimized such that it is guided directly onto sensor components in need of cooling of an electronic component, in particular to the printed circuit board, such that heat can be directly conducted thereby and be dissipated to the exterior via the housing wall.

The cooling body has a sufficiently large surface area for this purpose, such that with it large quantities of heat can be dissipated.

In this case as well, the thermal conduction layer can be directly connected to a surface of the printed circuit board or of a further electronic component placed thereon.

According to an advantageous embodiment, an image sensor and a lens are present in the optical sensor as sensor components.

The image sensor, i.e. imager, can be formed, for example, by a matrix-shaped CMOS or CCD array, the lens consists of a lens arrangement in the known manner.

In this case, the optical sensor can be designed as a code reader with which barcodes and 2D codes can be detected.

Advantageously, the image sensor and the lens are mounted on the top of the printed circuit board.

Advantageously, the cooling body has cooling ribs which radially run toward the lens enclosing the image sensor.

In this context, the lens and the image sensor are mounted in a tube which is fixed in place by means of the cooling ribs.

The cooling body with the cooling ribs thus fulfills a double function such that it not only serves to dissipate heat, but rather also to fix in place the lens with the image sensor.

It is expedient for the tube to be connected to the cooling ribs by a clamp connection or a screw connection.

Both variants result in the tube being securely fixed in place.

According to an advantageous embodiment, the cooling body has centering pins which can be inserted into boreholes of the printed circuit board.

In this context, by means of the centering pins, the image sensor with the lens is positioned relative to a borehole in the printed circuit board, the borehole forming a camera socket.

The boreholes are worked into the printed circuit board at the target position in advance, especially assisted by image processing, such that subsequently highly precise positioning of the image sensor in the camera socket is ensured by inserting the centering pins.

According to an optional embodiment, sensor components in the form of light-beam emitting light emitting diodes, which constitute an illumination unit, are mounted on the top of the printed circuit board.

The illumination units are thus arranged on the same side of the printed circuit board as the image sensor with the lens, preferably directly adjacent. The field of view of the image sensor is lit up with the light beams emitted by the light emitting diodes.

Advantageously, the light emitting diodes are disposed in recesses of the cooling ribs.

The recesses of the cooling body fulfill a stop function and prevent crosstalk, i.e. direct incidence of the light beams of the light-emitting diodes into the lens and the image sensor.

Furthermore, the cooling body can fulfill an additional function such that it carries a lens plate which serves for beam shaping of the light beams emitted by the light-emitting diodes.

According to an advantageous embodiment, a computer unit forming an electronic component is mounted on the bottom, the electronic component forming an evaluation unit in which the output signal is generated. The computer unit and the image sensor are arranged opposite one another on either side of the printed circuit board.

The computer unit is a micro controller, in particular.

The positioning of the computer unit on the bottom of the printed circuit board is optimally adapted to the positioning of the image sensor on the top, such that the image sensor can be connected to the computer unit via very short lines.

This is advantageous especially when the computer unit and the image sensor are connected via MIPI lines.

Due to the fact that the MIPI lines can be designed very short, undesired disturbances in the data transmission via these MIPI lines are being prevented.

### BRIEF DESCRIPTION OF THE DRAWINGS

The invention is explained below on the basis of the drawings. The Figures show:

FIG. 1: An exemplary embodiment of the optical sensor according to the invention.

FIG. 2: An individual depiction of components of the optical sensor according to FIG. 1.

FIG. 3: A schematic cross-sectional depiction of the optical sensor according to FIG. 1.

### DETAILED DESCRIPTION OF THE PREFERRED EMBODIMENTS

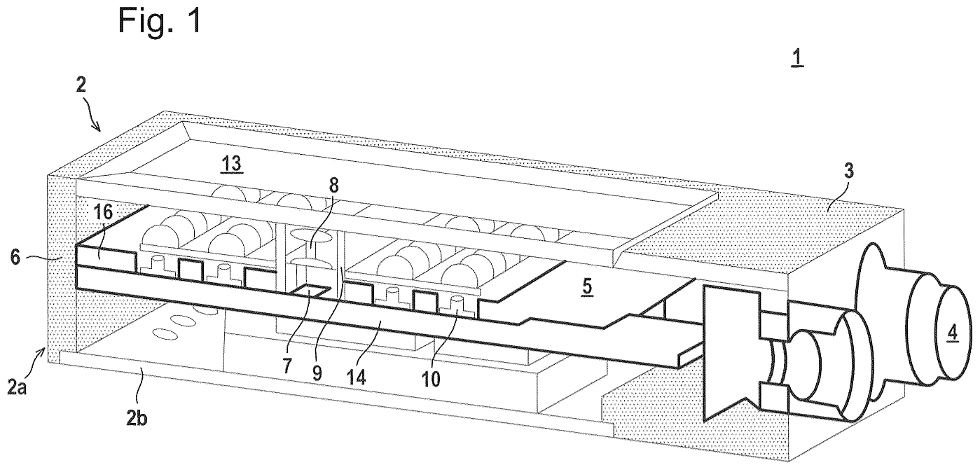

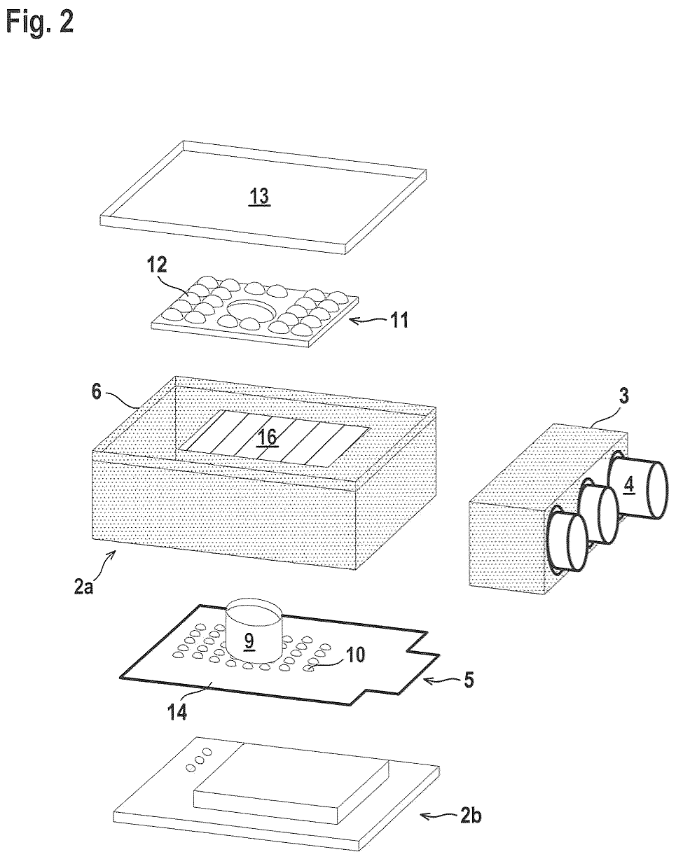

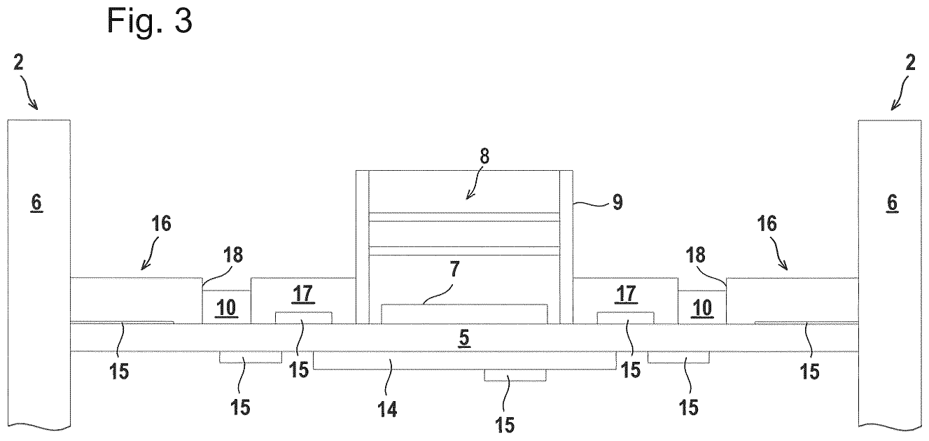

FIG. 1 shows an exemplary embodiment of the optical sensor 1 according to the invention. Components of the optical sensor are depicted in FIG. 2. FIG. 3 is a highly schematic, not-to-scale cross-sectional depiction of the optical sensor 1 along a narrow side of the optical sensor 1.

In the present case, the optical sensor 1 is designed as a code reader with which barcodes and 2D codes can be detected and decoded.

The optical sensor 1 has a housing 2 in which the electronic components and sensor components of the optical sensor 1 are integrated. The housing 2 consists of a material with high heat conductivity. For this purpose, the housing 2 consists of a metallic material. In the present case, the housing 2 consists of two zinc or aluminum die-cast parts, namely a housing body 2a and a housing cover 2b which closes off an opening on the bottom of the housing body 2a.

A plug cover 3 with electrical connections 4 is fastened laterally to the housing body 2a. The plug cover 3 can also consist of a zinc or aluminum die-cast part.

A printed circuit board 5 is present as the central electronic component which is fastened to the insides of housing walls 6 of the housing 2.

An image sensor 7 and a lens 8 assigned to it are mounted on the top of the printed circuit board as sensor components. The lens 8 is accommodated in a tube 9 which is fastened to the top of the printed circuit board 5. The tube 9 consists of optically opaque material and is open at its top.

Advantageously, the image sensor 7 consists of a matrix-shaped CCD or CMOS array. The lens 8 consists of an arrangement of lenses.

Furthermore, light-beam emitting light-emitting diodes 10, which constitute an illumination unit, are mounted on the top of the printed circuit board 5. The field of view of the image sensor 7 is lit up with the light beams of the illumination unit.

A lens plate 11 with lens elements 12 is assigned to the light-emitting diodes 10 by means of which a beam shaping of the light beams is effected.

A window 13 transparent for the light beams is inserted in an opening on the top of the housing 2.

A micro controller 14 which forms a computer unit and thus an electronic component of the optical sensor 1 is mounted on the bottom of the printed circuit board 5. Other processors can be provided instead of the micro controller 14. The micro controller 14 lies directly opposite the image sensor 7. The image sensor 7 is connected to the micro controller 14 by means of MIPI lines (not shown). Sensor signals of the image sensor 7 are read into the micro controller 14 via the MIPI lines, the micro controller 14 forming an evaluation unit for evaluating the sensor signals.

For detecting codes, the light beams of the light-emitting diodes 10 are guided into a detection area via the window 13 of the optical sensor 1. Light beams reflected by a code are guided to the image sensor 7 via the pane and the lens 8. The sensor signals thus generated in the image sensor 7, which contain the code information of the code, are evaluated in the micro controller 14 for decoding the code. The decoded code is output as an output signal by the optical sensor.

According to the invention, the housing 2 consisting of heat-conductive material serves for dissipating heat from the interior of the optical sensor 1.

For this purpose, sections of the housing 2 are connected via thermal conduction layers 15 directly, i.e. without an intervening air gap, to electronic components or sensor components such that heat arising there is dissipated via the thermal conduction layer 15 and the housing 2 and guided to the exterior, i.e. into the surroundings of the optical sensor 1.

The thermal conduction layers 15 have layer thicknesses in the μm range and can consist of thermal conduction pads or thermal pastes.

In the present case, there is a direct contacting of the housing cover 2b via thermal conduction layers 15 on the bottom of the printed circuit board 5, or respectively of the micro controller 14, such that heat generated in the printed circuit board 5, or respectively in the micro controller 14, is guided out to the exterior via the thermal conduction layers 15 present there and the housing cover 2b which is in contact with the thermal conduction layers 15.

Furthermore, a cooling body 16 is provided opening out on insides of housing walls 6, the cooling body 16 being designed monolithically with these housing walls 6 and being a constituent of the housing body 2a. Alternatively, the cooling body 16 can be heat-conductively connected to the housing body 2a.

The cooling body 16 runs in a plane perpendicular to the housing walls 6 at which it opens out. The cooling body 16 is dimensioned such that it lies flat on the printed circuit board 5, wherein further thermal conduction layers 15 are present between the printed circuit board 5 and the cooling body 16. Heat arising in the region of the printed circuit board 5 is thus guided out to the exterior directly via the thermal conduction layers 15, the cooling body 16 and the housing walls 6.

The cooling body 16 has cooling ribs 17 radially running toward the tube 9. The cooling ribs 17 serve to fix in place the tube 9, wherein the tube 9 is fixed to the cooling ribs 17 by means of a clamp connection. Alternatively, the cooling body 16 can constitute an annular segment with an inner thread into which the tube 9 is screwed.

As is evident from FIG. 3, in particular, the cooling body 16 has recesses 18 in which the light-emitting diodes 10 are mounted. In the region of the recesses 18, further thermal conduction layers 15 (not shown) can be present which create a heat-conductive connection between the light-emitting diodes 10 and the cooling body 16.

According to an advantageous further development, the cooling body 16 has centering pins which can be inserted into boreholes of the printed circuit board 5.

In this context, by means of the centering pins, the image sensor 7 with the lens 8 is positioned relative to a borehole in the printed circuit board 5, the borehole forming a camera socket.

The centering pins and the boreholes are not shown in the Figures.

### LIST OF REFERENCE NUMERALS

(1) Optical sensor
(2) Housing
(2a) Housing body
(2b) Housing cover
(3) Plug cover
(4) Connection
(5) Printed circuit board
(6) Housing wall
(7) Image sensor
(8) Lens
(9) Tube
(10) Light-emitting diodes
(11) Lens plate
(12) Lens element
(13) Window
(14) Microcontroller
(15) Thermal conduction layer
(16) Cooling body
(17) Cooling rib
(18) Recess

1. An optical sensor (1) with a housing (2) in which at least one sensor component designed for object detection as well as electronic components are arranged, wherein at least one electronic component generates an output signal in dependence upon sensor signals of the sensor component, characterized in that sections of the housing (2) consisting of heat-conductive material are connected to an electronic component and/or the sensor component via thermal conduction layers (15), such that heat generated therein is dissipated to the exterior via the housing (2).

2. The optical sensor (1) according to claim 1, characterized in that the housing (2) consists of a heat-conductive metallic material, and/or in that a thermal conduction pad or a thermal paste is provided as a thermal conduction layer (15).

3. The optical sensor (1) according to claim 2, characterized in that the metallic material is a zinc or aluminum die-cast.

4. The optical sensor (1) according to claim 1, characterized in that a printed circuit board (5) is present as an electronic component, the bottom of which is connected to a housing cover (2b) consisting of heat-conductive material or a housing wall (6) consisting of heat-conductive material via at least one thermal conduction layer (15).

5. The optical sensor (1) according to claim 1, characterized in that a cooling body (16) opens out on insides of housing wall segments consisting of heat-conductive material, the cooling body (16) consisting of heat-conductive material and being a constituent of the housing (2) or being heat-conductively connected thereto, and in that the cooling body (16) is in contact with at least one electronic component via at least one thermal conduction layer (15).

6. The optical sensor (1) according to claim 4, characterized in that the cooling body (16) is in contact with the top of the printed circuit board (5) via at least one thermal conduction layer (15).

7. The optical sensor (1) according to claim 1, characterized in that an image sensor (7) and a lens (8) are present as sensor components.

8. The optical sensor (1) according to claim 7, characterized in that the image sensor (7) and the lens (8) are mounted on the top of the printed circuit board (5), and/or in that the lens (8) and the image sensor (7) are mounted in a tube (9), which is fixed in place by means of the cooling ribs (17).

9. The optical sensor (1) according to claim 7, characterized in that the cooling body (16) has cooling ribs (17), which radially run toward the lens (8) enclosing the image sensor (7), and/or in that the tube (9) is connected to the cooling ribs (17) of the cooling body by a clamp connection or a screw connection.

10. The optical sensor (1) according to claim 4, characterized in that the cooling body (16) has centering pins which can be inserted into boreholes of the printed circuit board (5), wherein by means of the centering pins, the image sensor (7) with the lens (8) is positioned relative to a borehole in the printed circuit board (5), the borehole forming a camera socket.

11. The optical sensor (1) according to claim 4, characterized in that light-beam emitting light-emitting diodes (10), which constitute an illumination unit, are mounted on the top of the printed circuit board (5), wherein light-emitting diodes (10) are arranged in recesses (18) of the cooling ribs (17).

12. The optical sensor (1) according to claim 4, characterized in that a computer unit forming an electronic component is mounted on the bottom of the printed circuit board (5), the computer unit forming an evaluation unit in which the output signal is generated.

13. The optical sensor (1) according to claim 12, characterized in that the computer unit and the image sensor (7) are connected via MIPI lines.

14. The optical sensor (1) according to claim 1, characterized in that the outside of the housing is painted with heat dissipation paint.

15. The optical sensor (1) according to claim 1, characterized in that it is a code reader.
